(19) United States
(12) Patent Application Publication
(10) Pub. No.: US 2025/0149454 A1
(43) Pub. Date: May 8, 2025

(54) Semiconductor Device and Methods of Making and Using Pre-Molded Bridge Die

(71) Applicant: STATS ChipPAC Pte. Ltd., Singapore (SG)

(72) Inventors: Linda Pei Ee Chua, Singapore (SG); Kai Chong Chan, Singapore (SG); Yaojian Lin, Jiangyin (CN)

(73) Assignee: STATS ChipPAC Pte. Ltd., Singapore (SG)

(21) Appl. No.: 18/503,013

(22) Filed: Nov. 6, 2023

(51) Int. Cl. H01L 23/538; H01L 21/48; H01L 21/56; H01L 23/31

(52) U.S. Cl. CPC H01L 23/5381; H01L 21/4853; H01L 21/4857; H01L 21/563; H01L 21/565; H01L 23/3128; H01L 23/3135; H01L 23/5383; H01L 23/5386

(57) ABSTRACT

A semiconductor device has a first interconnect structure. A pre-molded bridge die is disposed over the first interconnect structure. An encapsulant is deposited over the pre-molded bridge die. A second interconnect structure is disposed over the encapsulant and pre-molded bridge die. A first semiconductor die is disposed over the second interconnect structure within a footprint of the pre-molded bridge die. A second semiconductor die is disposed over the second interconnect structure within the footprint of the pre-molded bridge die.

### FIELD OF THE INVENTION

The present invention relates in general to semiconductor devices and, more particularly, to a semiconductor device and methods of making and using pre-molded bridge die.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices may contain multiple electrical components, e.g., one or more semiconductor die and myriad discrete components to support the semiconductor die, disposed on one or more substrates to perform necessary electrical functions. Highly integrated packages with several components are commonly referred to as system-in-package (SiP) modules. SiP modules often have multiple semiconductor die that must communicate with each other at very high bandwidths. Conductive traces formed at the package level may be insufficient to support the necessary bandwidth.

Many SiP packages utilize bridge die to facilitate high-bandwidth communication between components in a SiP device. Bridge die are semiconductor die that may have no circuits formed in their active surface but have fine-pitched interconnects formed over them. Bridge die can be disposed between two other semiconductor die, then both semiconductor die are connected to each other through the bridge die to increase the available data bandwidth between them.

Bridge die are helpful for advanced SiP modules, but introduce additional design constraints due to the extra component required. Therefore, a need exists for improved bridge die structures and topologies.

### BRIEF DESCRIPTION OF THE DRAWINGS

FIGS. 1a-1d illustrate a semiconductor wafer with a plurality of bridge die separated by a saw street;

FIGS. 2a-2e illustrate molding a bridge die;

FIGS. 3a-3m illustrate forming a system-in-package module with the pre-molded bridge die;

FIG. 4 illustrates a system-in-package module with a bridge die that is not pre-molded;

FIGS. 5a-5h illustrate forming a fan-out interconnect structure over the pre-molded bridge die;

FIGS. 6a and 6b illustrate an additional protective layer formed over the bridge die; and

FIGS. 7a and 7b illustrate an electronic device with the system-in-package modules.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

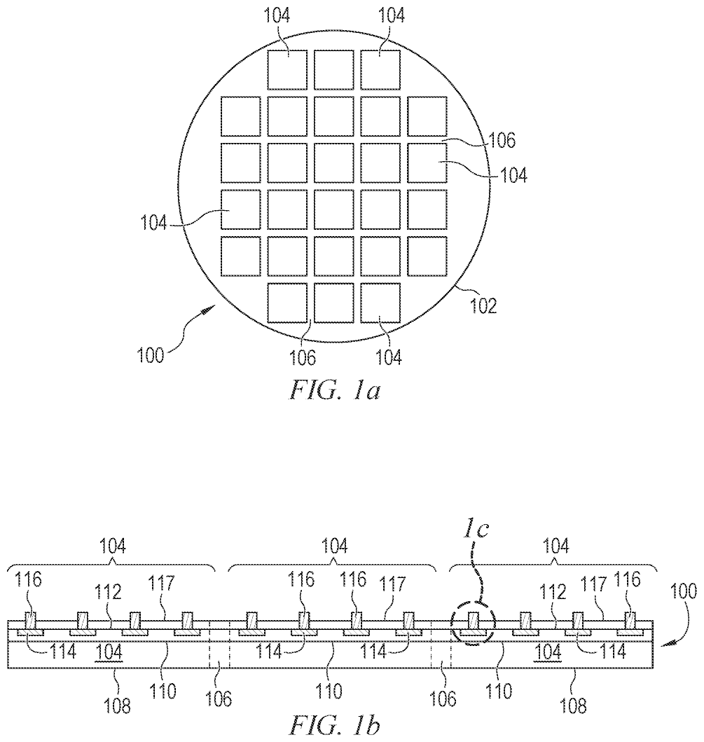

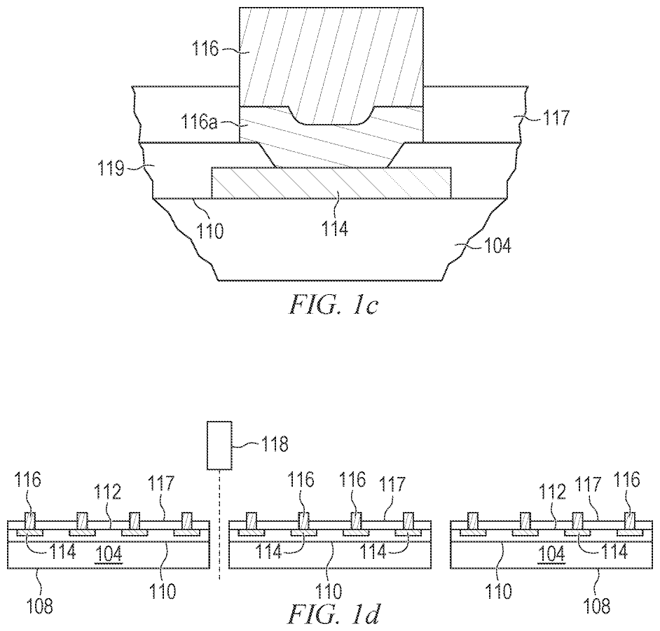

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die, bridge die, or other components 104 is formed on wafer 100 separated by a non-active, inter-die wafer area or saw street 106. Saw street 106 provides cutting areas to singulate semiconductor wafer 100 into individual bridge die 104. In one embodiment, semiconductor wafer 100 has a width or diameter of 100-450 millimeters (mm). Wafer 100 can include hundreds or thousands of die 104.

FIG. 1b shows a cross-sectional view of a portion of semiconductor wafer 100. Each bridge die 104 has a back or non-active surface 108 and an active surface 110 optionally containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as a digital signal processor (DSP), application specific integrated circuits (ASIC), memory, or other signal processing circuit. Bridge die 104 may also contain IPDs, such as inductors, capacitors, and resistors, for RF signal processing.

Alternatively, bridge die 104 has no circuits formed in active surface 110 and is only used for the interconnect structure 112 formed over active surface 110. Interconnect structure 112 includes fine-pitched conductive traces, e.g., less than two micrometers (microns) in both line width and spacing between the lines. Interconnect structure 112 may have one or more than one layer of conductive traces with insulating layers formed between the layers. Interconnect structure 112 is illustrated as just a region because the pitch of the interconnects are too fine to illustrate other than conceptually. The area identified as interconnect structure 112 in the figure is occupied by a fine-pitched interconnect structure in any suitable configuration, e.g., electrically coupling pairs of contact pads 114 to each other on opposite sides of a bridge die 104.

Interconnect structure 112 includes contact pads 114 formed at the top of the interconnect structure for external connections to interconnect structure 112. Contact pads 114 are larger than two microns to allow conductive vias or other conductive structures to contact or be formed on the contact pads and thereby electrically connect to the underlying fine-pitched conductive traces of interconnect structure 112.

Conductive traces of interconnect structure 112 and contact pads 114 are formed over active surface 110 using physical vapor deposition (PVD), chemical vapor deposition (CVD), electrolytic plating, electroless plating, or another suitable metal deposition process. Conductive traces of interconnect structure 112 and contact pads 114 can be one or more layers of aluminum (Al), copper (Cu), tin (Sn), nickel (Ni), gold (Au), silver (Ag), or other suitable electrically conductive material. Contact pads 114 include an under-bump metallization (UBM) in some embodiments.

Interconnect structure 112 includes insulating layers formed over and between the conductive traces. Insulating layers of interconnect structure 112 contain one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), and other material having similar insulating and structural properties. Insulating layers can be formed using PVD, CVD, printing, lamination, spin coating, spray coating, sintering, thermal oxidation, or another suitable process. Interconnect structure 112 can include any number of conductive layers and insulating layers interleaved over each other.

Conductive microposts, microbumps, or micropillars 116 are formed on contact pads 114 of each bridge die 104 to provide external interconnection. Conductive micropillars 116 are typically formed by depositing conductive material into openings of a photolithographic layer and then removing the photolithographic layer. The metal can be any of the materials mentioned above for conductive layers. In one embodiment, micropillars 116 have a copper core with a Ti/Cu plating 30 microns thick. Micropillars 116 represent just one possible interconnect method. Other embodiments use bond wires, conductive paste, stud bumps, solder bumps, or any other suitable type of electrical interconnect.

An insulating or passivation layer 117 is deposited over interconnect structure 112 and micropillars 116. Insulating layer 117 is formed as described above for insulating layers and of any of the insulating materials mentioned above. Insulating layer 117 is formed to a thickness such that micropillars 116 extend above a top surface of the insulating layer, i.e., a thickness of the insulating layer is less than a height of the micropillars.

FIG. 1c shows a detailed view of a micropillar 116 in one embodiment. An optional passivation layer 119 is formed on bridge die 104 prior to forming micropillar 116. Micropillar 116 can include a UBM 116a formed in the same mask opening as the micropillar itself. Insulating layer 117 is a polyimide layer. Interconnect structure 112 exists only as conductive traces extending between contact pads 114 over active surface 110.

In FIG. 1d, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

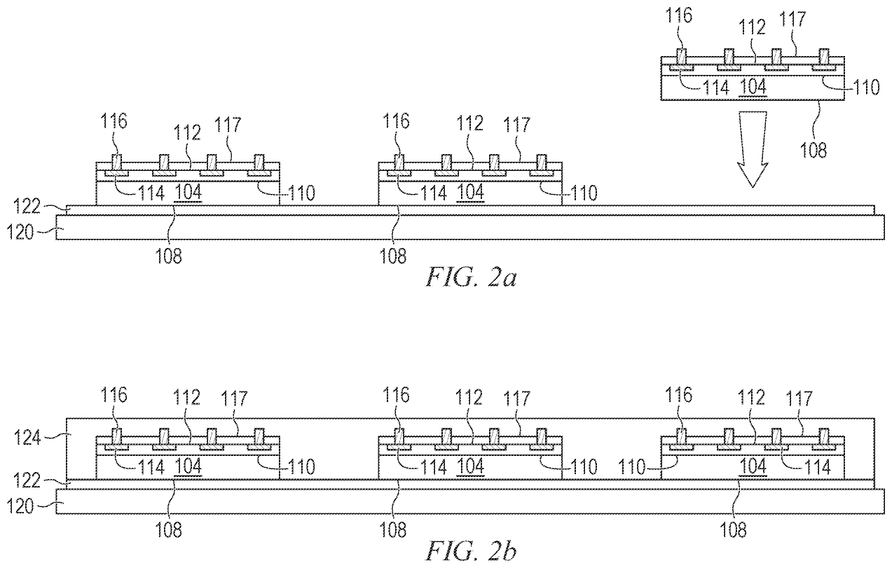

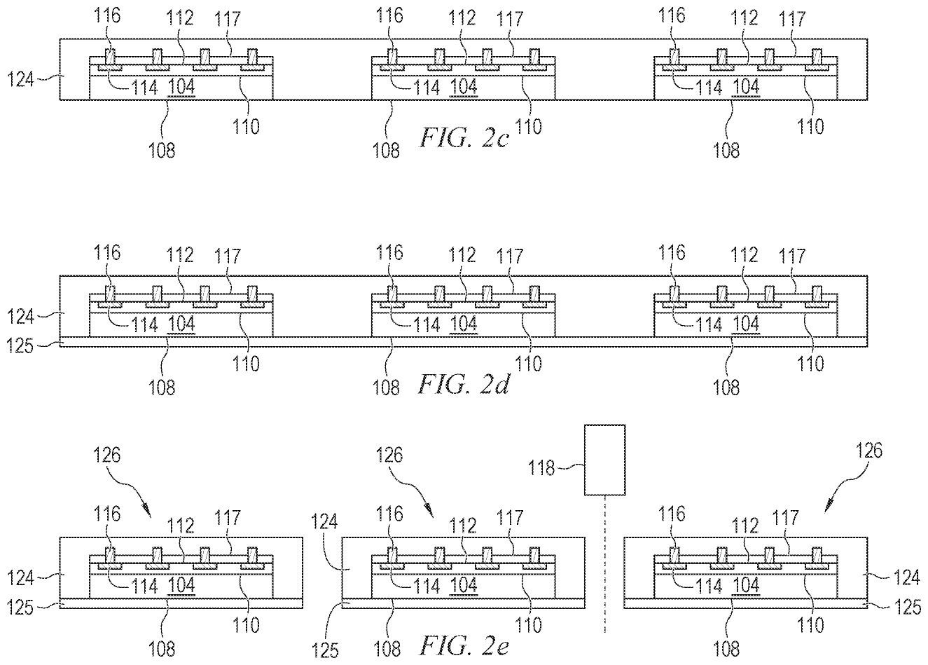

FIGS. 2a-2e illustrate a process of pre-molding bridge die 104. FIG. 2a shows a cross-sectional view of a portion of a carrier or temporary substrate 120 containing sacrificial base material such as silicon, polymer, beryllium oxide, glass, or other suitable low-cost, rigid material for structural support. An interface layer or double-sided tape 122 is formed or disposed over carrier 120 as a temporary adhesive bonding film, etch-stop layer, thermal release layer, or UV release layer. Carrier 120 can be a round or rectangular panel with capacity for multiple bridge die 104 to be processed at once. While only three bridge die 104 are illustrated, tens, hundreds, or thousands of modules may be processed together on a common carrier 120.

Bridge die 104 are disposed over carrier 120 with back surfaces 108 of the bridge die oriented toward the carrier. Micropillars 116 extend upward away from carrier 120. In FIG. 2b, encapsulant or molding compound 124 is deposited over and around carrier 120, bridge die 104, and micropillars 116 using a paste printing, compressive molding, transfer molding, liquid encapsulant molding, vacuum lamination, spin coating, or another suitable applicator. Encapsulant 124 can be liquid or granular polymer composite material, such as epoxy resin, epoxy acrylate, or polymer, with or without an added filler. In another embodiment, encapsulant 124 is a laminated mold sheet or film with or without fillers. Encapsulant 124 is non-conductive, provides structural support, and environmentally protects bridge die 104 from external elements and contaminants. Encapsulant 124 completely covers the top and side surfaces of micropillars 116. In another embodiment, encapsulant 124 is deposited to have a top surface coplanar to the top surfaces of micropillars 116, e.g., by using film-assisted molding.

Carrier 120 is debonded and removed from the panel of bridge die 104 and encapsulant 124 in FIG. 2c. The adhesive properties of interface layer 122 are reduced by thermal, ultraviolet, laser, or other energy application in some embodiments before mechanically removing carrier 120 from the bridge die panel.

In FIG. 2d, a die-attach film (DAF) tape 125 is mounted onto encapsulant 124 and the now-exposed back surface 108 of bridge die 104, which are coplanar. DAF tape 125 is double-sided adhesive tape that sticks to the panel of encapsulant 125 and bridge die 104 due to its adhesive properties. The side of DAF tape 125 opposite bridge die 104 will typically be covered by a non-adhesive film until a manufacturer peels off the non-adhesive film to mount one of the bridge die into a package.

In FIG. 2e, bridge die 104 are singulated from each other through encapsulant 124 and DAF tape 125 to form separate pre-molded bridge die 126. Singulation through encapsulant 124 can occur using the same saw blade or laser cutting tool 118 as used above to singulate the wafer, or any other suitable means can be used. Pre-molded bridge die 126 are referred to as pre-molded because bridge die 104 are molded within encapsulant 124 prior to incorporating the bridge die into a system-in-package (SiP) module or other semiconductor package. In some embodiments, pre-molded bridge die 126 may have an additional alignment marker feature, such as an attached copper ball or dummy die, for die attach.

As an alternative molding process, encapsulant 124 may be deposited prior to fully singulating semiconductor wafer 100. Trenches can be formed into saw streets 106 to create side surfaces of bridge die 104 exposed within the trenches. Encapsulant 124 is deposited over active surface 110 and into the trenches in saw street 106. Wafer 100 is backgrinded to remove remaining semiconductor material within saw street 106. Then, bridge die 104 are singulated from each other through encapsulant 124, which has been made the same thickness as the bridge die through backgrinding wafer 100.

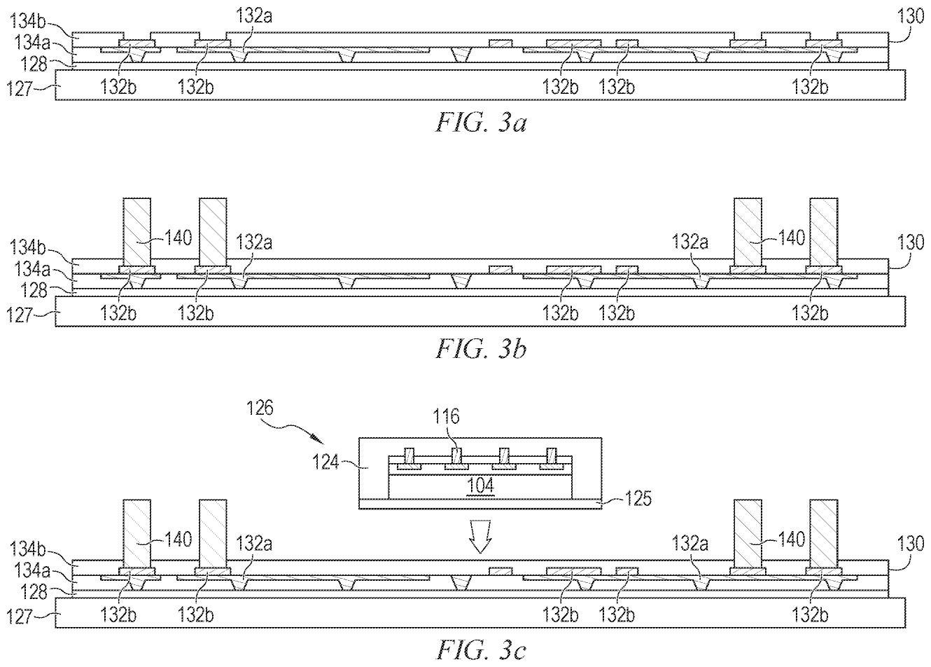

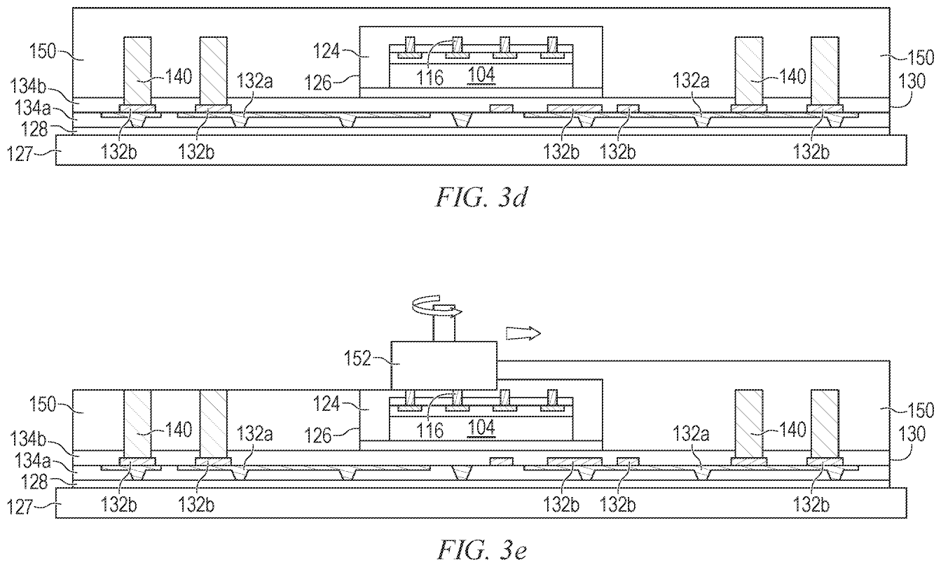

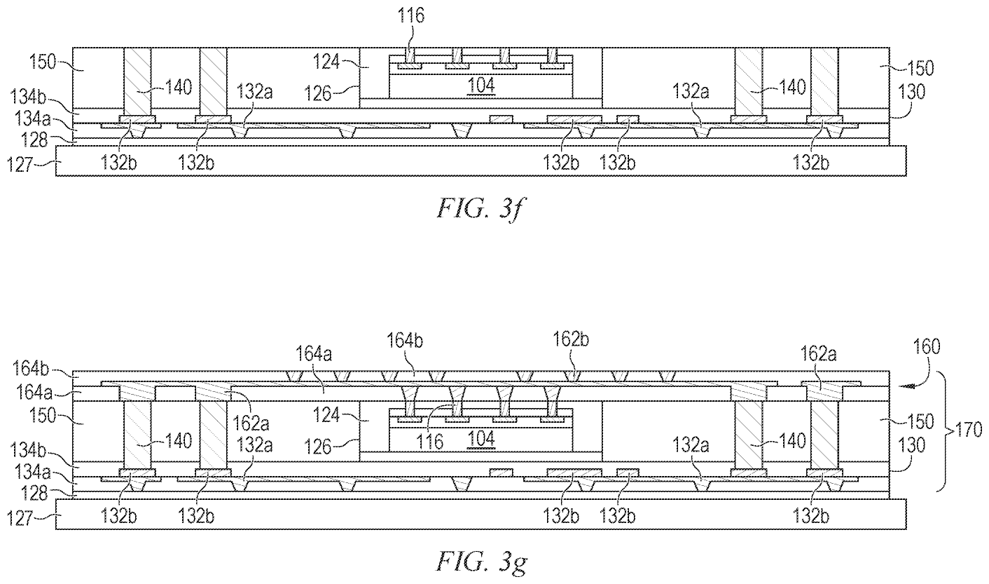

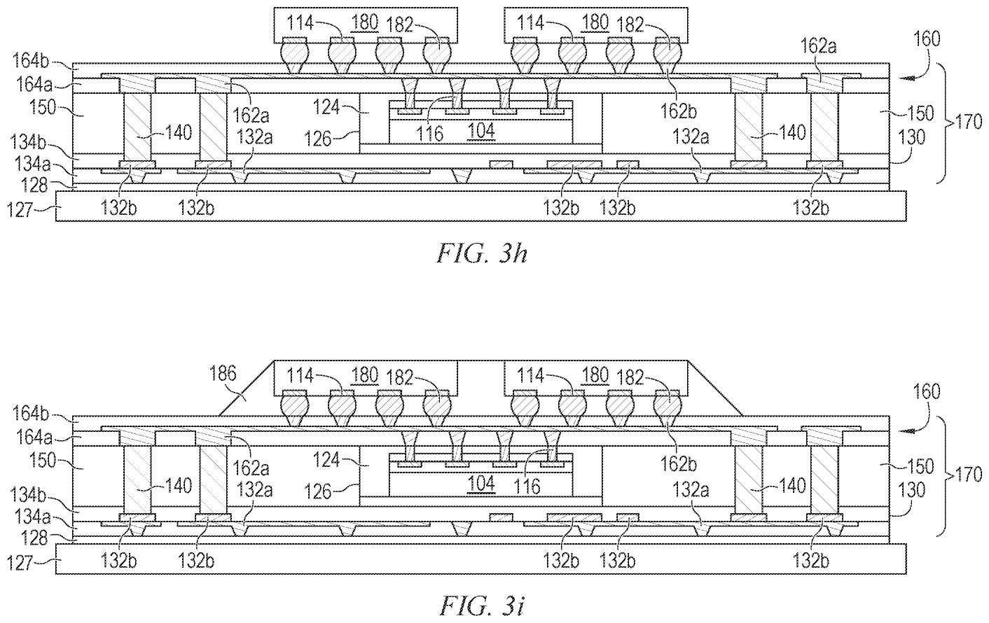

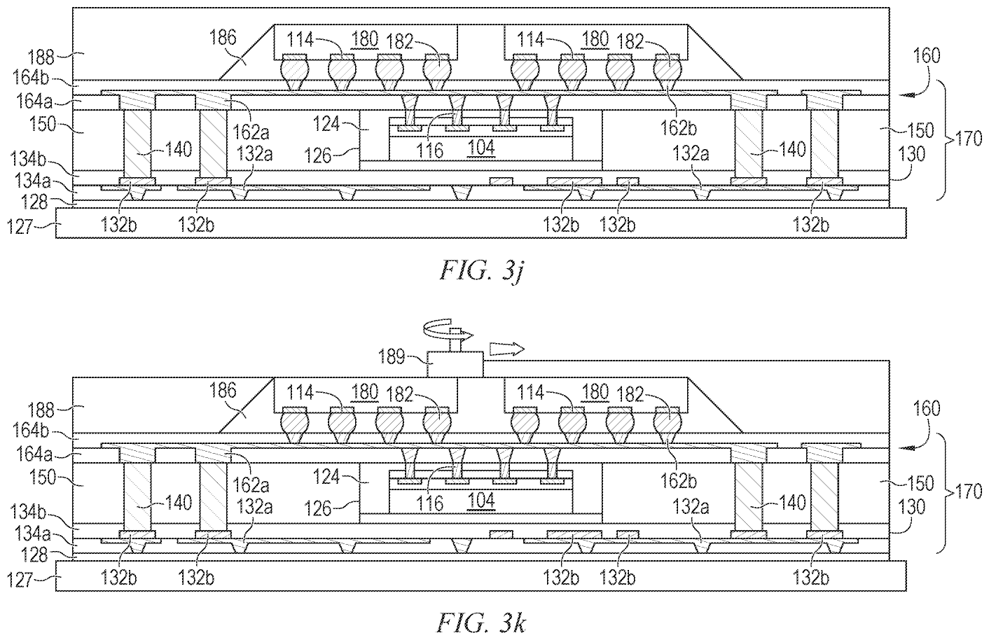

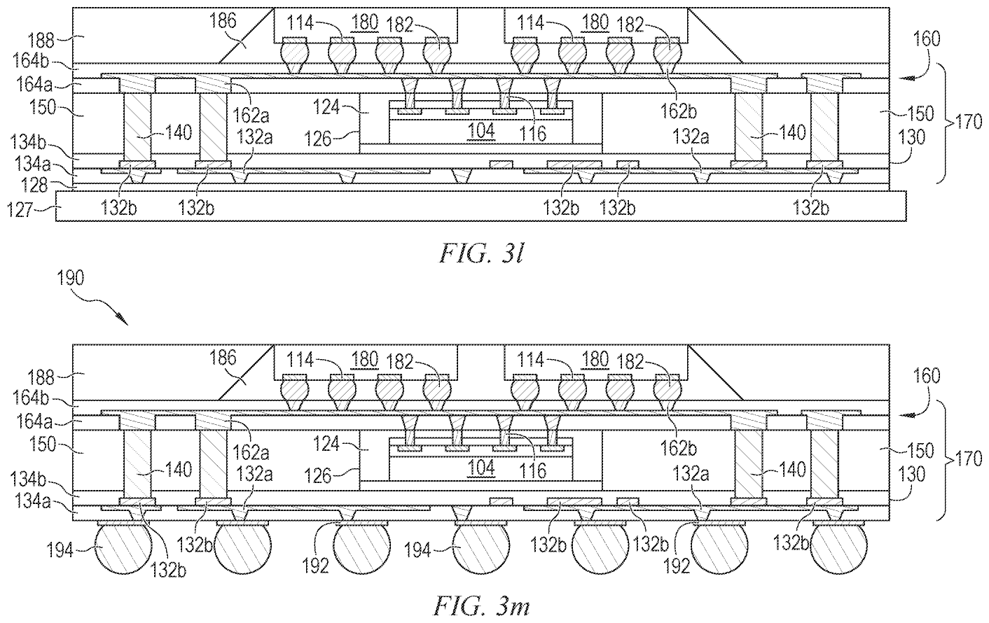

FIGS. 3a-3m show a process of forming a SiP module incorporating pre-molded bridge die 126. In FIG. 3a, an interconnect structure 130 is formed or disposed on carrier 127 with interface layer 128. Carrier 127 can be the same or different from carrier 120. Carrier 127 can be the same type or size as carrier 120 or another type of carrier mentioned above can be used. Interface layer 128 can be any suitable type of interface layer as mentioned above for interface layer 122. Carrier 127 can be a round or rectangular panel with capacity for multiple SiP modules to be formed at once. While only one unit is illustrated being formed, tens, hundreds, thousands, or more modules may be formed together on a common carrier 120 using the steps shown and described below performed en masse.

Interconnect structure 130 includes one or more conductive layers 132 and one or more insulating layers 134. The specific illustrated embodiment shows a pair of insulating layers 134a and 134b and a pair of conductive layers 132a and 132b built up as a stack, but any suitable number of layers can be used to accomplish the desired signal routing. Conductive layers 132 can be formed using the materials and methods described above for the conductive layers of interconnect structure 112. Conductive layers 132 provide conductive traces for horizontal electrical interconnect across interconnect structure 130 and conductive vias for vertical electrical interconnect between surfaces and layers of the interconnect structure. Portions of conductive layers 132 can be electrically common or electrically isolated depending on the design and function of the package being formed.

In some embodiments, interconnect structure 130 is a preformed interposer or substrate that is completely formed prior to disposing the interconnect structure onto carrier 127. In another embodiment, interconnect structure 130 is formed directly on carrier 127 by successively forming a plurality of insulating layers 134 and conductive layers 132 on the carrier. Interconnect structure 130 is typically large enough to accommodate all of the SiP modules being formed at once on carrier 120 and then singulated along with the final modules. In other embodiments, a separate interconnect structure 130 is provided or formed for each SiP module.

Openings are formed through the bottom insulating layer 134a to allow conductive vias of conductive layer 132a to extend down to the bottom of interconnect structure 130 for external interconnect. Similarly, top insulating layer 134b has openings formed over contact pads of conductive layer 132b for subsequent interconnect. In other embodiments, conductive layer 132a, conductive layer 132b, or both, are formed on the outmost surfaces of interconnect structure 130 so no opening or via through insulating layers 134 are necessary for interconnection. Conductive traces of conductive layer 132a or 132b interconnect the vias of conductive layer 132a and the contact pads of conductive layer 134b to implement the desired signal routing. Any type of package substrate or leadframe is used for interconnect structure 130 in other embodiments.

In FIG. 3b, conductive pillars 140 are formed on interconnect structure 130 at points where conductive layer 132b is exposed as contact pads through openings of insulating layer 134b. Conductive pillars 140 are formed by depositing conductive material into photolithographic mask openings in one embodiment. In another embodiment, conductive pillars 140 are preformed and then picked and placed onto interconnect structure 130. Solder or solder paste can be used to connect pillars 140 to interconnect structure 130. Conductive pillars 140 can be formed of any of the conductive materials mentioned above and using any suitable manufacturing process.

Pre-molded bridge die 126 are picked and placed over, and then mounted to, interconnect structure 130 in FIG. 3c. Encapsulant 124 protects bridge die 104 during the physical handling of the pick and place process. DAF tape 125 has an adhesive surface exposed that sticks to insulating layers 134. A protective non-adhesive film is peeled before mounting if used. In other embodiments, a separate die attach adhesive is dispensed onto interconnect structure 130 instead of using DAF tape 125. The height of conductive pillars 140 is selected so that the tops of the conductive pillars will be approximately the same height over interconnect structure 130 as the tops of micropillars 116. In other embodiments, the heights differ and may be made equal using a subsequent planarization step.

In FIG. 3d, an encapsulant 150 is deposited over and around interconnect structure 130, pre-molded bridge die 126, and conductive pillars 140. Encapsulant 150 is deposited using any of the materials and methods described above for encapsulant 124. Encapsulant 150 completely covers the tops of conductive pillars 140 and pre-molded bridge die 126.

FIG. 3e shows planarization of encapsulant 150, conductive pillars 140, and pre-molded bridge die 126 using a mechanical grinder 152. Chemical-mechanical planarization or another suitable method is used in other embodiments. FIG. 3f shows encapsulant 150 after planarization. Planarization removes a top portion of encapsulant 124 from pre-molded bridge die 126 to expose top surfaces of micropillars 116. A small portion of conductive pillars 140 and micropillars 116 can be removed to ensure all conductive pillars and micropillars are exposed from encapsulant 150 for electrical interconnect. Planarization leaves the top surfaces of conductive pillars 140 and micropillars 116 coplanar with each other and with the top surface of encapsulant 150.

In other embodiments, film-assisted molding, or another suitable molding technique, is used to leave conductive pillars 140 and micropillars 116 exposed without a separate planarization step. The pre-molding of bridge die 104 within encapsulant 124 reduces the likelihood of delamination during grinding. In another embodiment, laser, mechanical, or chemical etching is used to form an opening through encapsulant 150 down to micropillars 116 and conductive pillars 140 instead of planarization.

In FIG. 3g, an interconnect structure 160 is formed or disposed over encapsulant 150. Interconnect structure 160 is formed and structured similarly to interconnect structure 130 on the opposite side of encapsulant 150, with conductive layers 162 interleaved between insulating layers 164. Two conductive layers 162a and 162b, and two insulating layers 164a and 164b, are illustrated. However, any suitable number of insulating and conductive layers can be interleaved over each other to implement the desired signal routing. Interconnect structure 160 can be formed directly on top of encapsulant 150 and pre-molded bridge die 126 or formed separately and disposed onto the encapsulant and pre-molded bridge die.

Conductive layers 162 include conductive vias that extend down to the bottom surface of interconnect structure 160 to physically and electrically contact conductive pillars 140 and micropillars 116. Contact pads or conductive vias of conductive layer 162b are exposed at the top surface of interconnect structure 160 to allow mounting of electrical components onto the interconnect structure.

In combination, interconnect structure 130, conductive pillars 140, pre-molded bridge die 126, encapsulant 150, and interconnect structure 160 form a fan-out interposer 170. Interposer 170 can operate as the package substrate for a semiconductor package and has bridge die 104 embedded within the interposer as part of pre-molded bridge die 126.

In FIG. 3h, forming a SiP module with interposer 170 as the package substrate begins by mounting additional semiconductor die 180 and any other desired components onto interconnect structure 160. Semiconductor die 180 are formed similarly to bridge die 104, but may not have such a fine-pitched interconnect structure 112. Semiconductor die 180 still have conductive and insulating layers stacked on their active surfaces culminating with contact pads 114 exposed over the active surfaces of each die.

An electrically conductive bump material is deposited over contact pads 114 of semiconductor die 180, typically at the wafer level, using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to contact pads 114 using a suitable attachment or bonding process. In one embodiment, the bump material is reflowed by heating the material above its melting point to form bumps 182. Bumps 182 can also be compression bonded or thermocompression bonded to contact pads 114. After semiconductor die 180 are disposed over interposer 170, bumps 182 are reflowed to mechanically and electrically couple semiconductor die 180 to interconnect structure 160.

As only one simplified example out of nearly infinite possibilities, FIG. 3h shows forming a SiP module with one bridge die 104 embedded within interposer 170 and two main die 180 on the interposer connected together by the bridge die. Main die 180 can be any type of die that serve the main function of the package being formed, e.g., ASICs, microprocessors, central processing units (CPU), graphical processing units (GPU), accelerators, logic die, high-bandwidth memory (HBM), I/O die, or NAND flash. Main die 180 can be identical to each other or different, e.g., a CPU and a GPU. More than two die are coupled together by one bridge die 104 in other embodiments. More than one bridge die can also be used. Additional bridge die 104, with or without pre-molding, may be placed on top of interposer 170 if convenient for package layout. Any other suitable components, e.g., other semiconductor die or discrete active or passive electrical components, can be mounted onto interconnect structure 130 along with pre-molded bridge die 126 or onto interconnect structure 160 along with main die 180.

Main die 180 are each separately coupled to bridge die 104 by interconnect structure 160 and then to each other through the bridge die. In plan view, each main die 180 overlaps bridge die 104 within interposer 170, which allows a direct vertical connection between the main die and bridge die. Bridge die 104 provides faster and higher density interconnect than what is available through interconnect structure 160. Only a small portion of the interconnect between main die 180 occurs in interconnect structure 160, while most of the interconnect distance is through bridge die 104. Components are not to scale, and the proportion of distance covered by bridge die 104 in practice will be much greater than illustrated. In some embodiments, main die 180 are also coupled directly to each other through interconnect structure 160. For instance, high bandwidth data lines between the two main die may utilize bridge die 104 while slower control signals are connected directly without the bridge die.

In FIG. 3i, a mold underfill 186 is dispensed between interposer 170 and main die 180. Capillary action draws mold underfill 186 under the die to completely fill in the gaps between each die and interposer 170. In some embodiments, mold underfill 186 also flows up between adjacent die 180. A second encapsulant 188 is deposited over interposer 170 and main die 180 in FIG. 3j. Encapsulant 188 is deposited using similar methods and materials as disclosed above for encapsulant 150. In some embodiments, film-assisted molding is used to leave the back surfaces of die 180 exposed from encapsulant 188.

Encapsulant 188 can alternatively be backgrinded to expose the die using backgrinder 189 or another suitable method as shown in FIG. 3k. In other embodiments, encapsulant 188 is left covering semiconductor die 180. FIG. 3l illustrates encapsulant 188 made coplanar to back surfaces of semiconductor die 180.

A SiP module 190 is completed by removing interposer 170 from carrier 127 and forming UBM 192 and solder bumps 194 on the newly-exposed surface of interconnect structure 130 in FIG. 3m. UBM 192 is formed of multiple conductive layers including a wetting layer, barrier layer, and adhesion layer in some embodiments. Each UBM 192 is formed directly on an exposed conductive via of conductive layer 132 to provide electrical connection from an external system to the components within SiP module 190. Bumps 194 are formed on UBM 192 as described for bumps 182 on contact pads 114.

The panel is singulated through interposer 170 and encapsulant 188 to separate individual SiP modules 192 from each other, and then picked and placed into a tape-and-reel or other container for delivery. SiP module 192 has a bridge die 104 included as part of pre-molded bridge die 126. The additional mold layer provided by encapsulant 124 reduces the likelihood of dielectric layer delamination during the grinding step shown in FIG. 3e. In addition, encapsulant 124 can be made a different material from encapsulant 150 to provide better warpage and structural rigidity. Encapsulant 124 also protects bridge die 104 during handling for die attach in FIG. 3c.

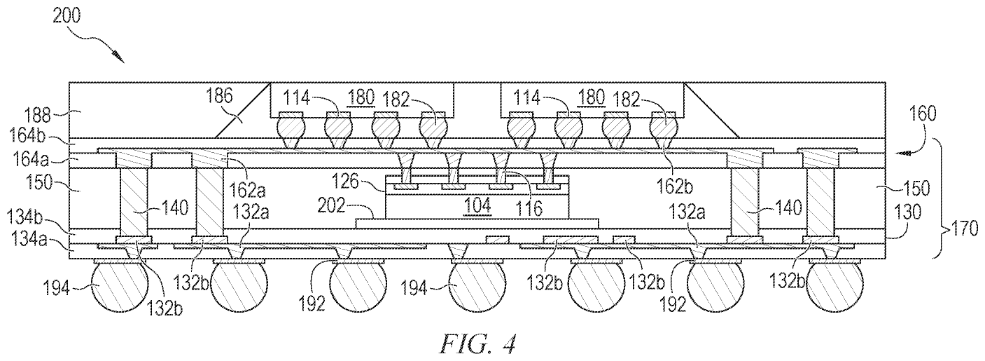

FIG. 4 illustrates an embodiment similar to SiP module 192 but showing SiP module 200 with a bridge die 104 that is not pre-molded. SiP module 200 is formed as shown in FIGS. 3a-3m, but bridge die 104 is included after singulation in FIG. 1d and without pre-molding as shown in FIGS. 2a-2e. DAF tape 202 can be disposed on interconnect structure 130 prior to mounting bridge die 104, or on bridge die 104 first. Alternatively, a liquid adhesive can be dispensed between bridge die 104 and interconnect structure 130.

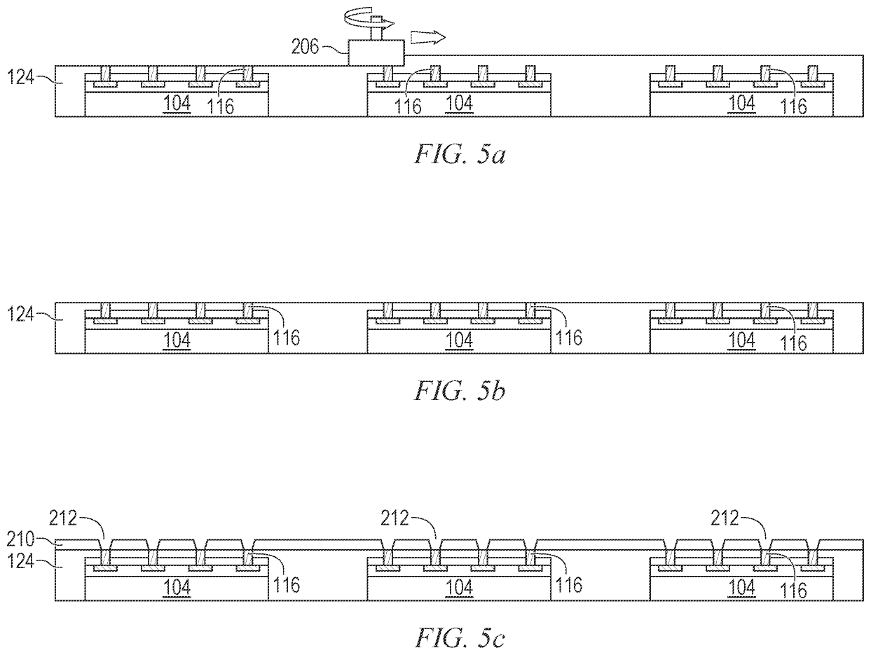

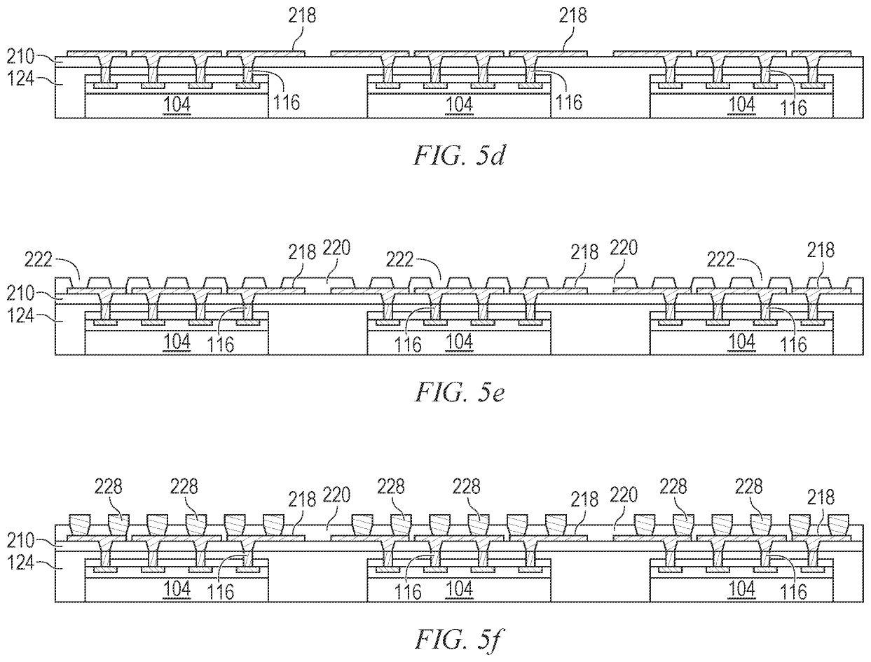

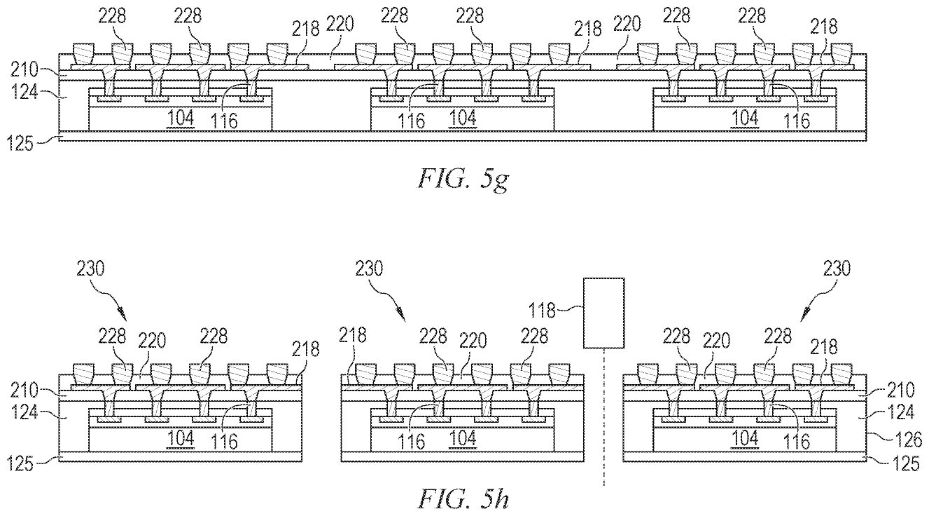

FIGS. 5a-5h illustrate forming a redistribution layer or fan-out interconnect structure over a pre-molded die. Continuing from FIG. 2c, the panel of encapsulant 124 and bridge die 104 is planarized over micropillars 116 to expose the micropillars from the encapsulant. Top surfaces of micropillars 116 are made coplanar to the top surface of encapsulant 124 as shown in FIG. 5b.

In FIG. 5c, an insulating layer 210 is formed over the coplanar surfaces of encapsulant 124 and micropillars 116. Insulating layer 210 is formed using any of the processes and materials mentioned above for other insulating or passivation layers. Openings 212 are formed through insulating layer 210 to expose micropillars 116 using photolithography, mechanical or chemical etching, laser ablation, or another suitable method for subsequent electrical interconnection to the micropillars.

In FIG. 5d, conductive layer 218 is formed over insulating layer 210 and into openings 212 to contact micropillars 116. Conductive layer 218 is formed using any of the processes and materials mentioned above for conductive layers. Conductive layer 218 is patterned to include conductive traces in a fan-out pattern and optionally contact pads where overlying interconnect structures will be formed or disposed. In FIG. 5e, insulating layer 220 is formed over conductive layer 218 as mentioned above for insulating layer 210. Openings 222 are formed through insulating layer 220 to expose portions of conductive layer 218 for subsequent electrical interconnect.

In FIG. 5f, contact pads or UBM 228 are formed in openings 222 to provide external interconnect to bridge die 104 through conductive layer 218 and micropillars 116.

In FIG. 5g, DAF tape 125 is disposed on the back surfaces of encapsulant 124 and bridge die 104 as described above. Bridge die 104 are singulated from each other through insulating layer 220, insulating layer 210, encapsulant 124, DAF tape 125, and optionally conductive layer 218 to separate the bridge die into separate units of pre-molded bridge die 230 in FIG. 5h. Pre-molded bridge die 230 have a bridge die 104 pre-molded in encapsulant 124 with a fan-out interconnect structure formed over the bridge die and encapsulant. Pre-molded bridge die 230 can be incorporated into a SiP device as described above.

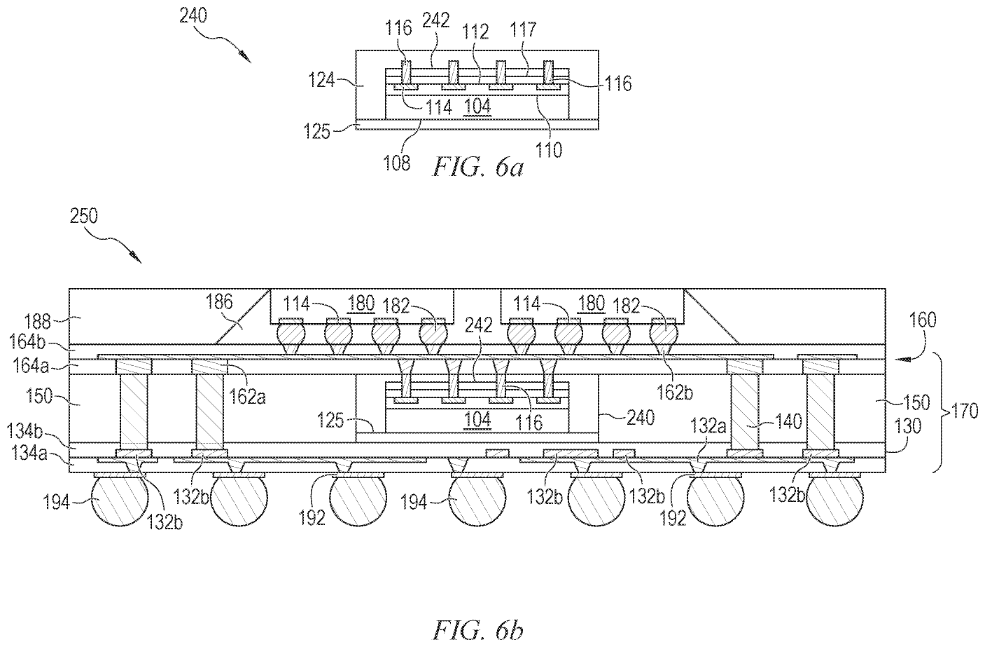

FIGS. 6a and 6b illustrate pre-molded bridge die 240 with an extra protective layer 242 used on bridge die 104. Bridge die 104 is formed with protective layer 242 formed at the wafer 100 level, over insulating layer 117 at the stage shown in FIG. 1b above. The material for protective layer 242 can be a mold sheet film with SiO2 fillers and polymer resin, e.g., Ajinomoto ABF materials. Alternatively, a mold compound, e.g., Nagase liquid mold compound, is applied using a molding process. In other embodiments, any material and process described above for an encapsulant or insulating layer can be used to form protective layer 242. A thermal curing process is used after applying the film or mold compound if necessary.

In addition to having a protective function during processing of bridge die 104, protective layer 242 helps to alleviate coefficient of thermal expansion (CTE) mismatch between bridge die 104 and main die 180 disposed over interposer 170. CTE of protective layer 242 is between 4-30 ppm/K in one embodiment. In another embodiment, CTE of protective layer 242 is between 5 and 10 ppm/K. The top surface of protective layer 242 is equal to or extends over micropillars 116 in some embodiments. Protective layer 242 optionally has a sloped surface around each micropillar 116.

FIG. 6b shows SiP module 250 formed with pre-molded bridge die 240. SiP module 250 is formed as described above for SiP module 190, but using pre-molded bridge die 240 in place of pre-molded bridge die 126. Protective layer 242 can also be added to bridge die 104 without pre-molding as shown in FIG. 4, or any other bridge die embodiment disclosed above or below.

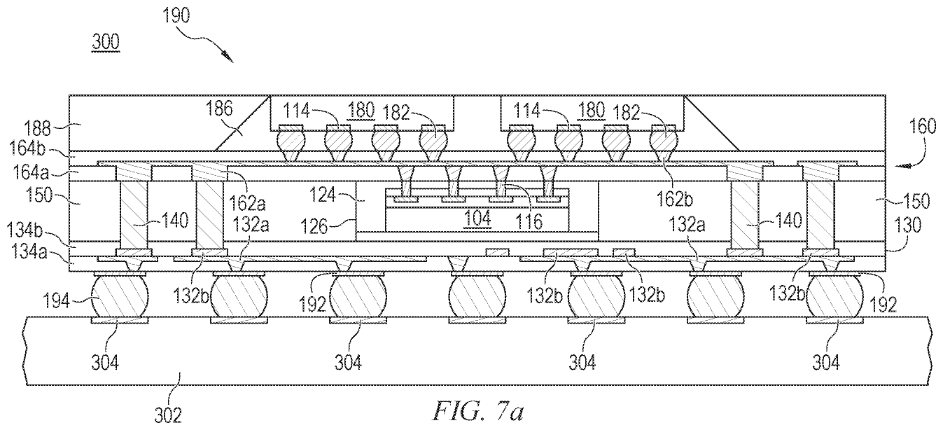

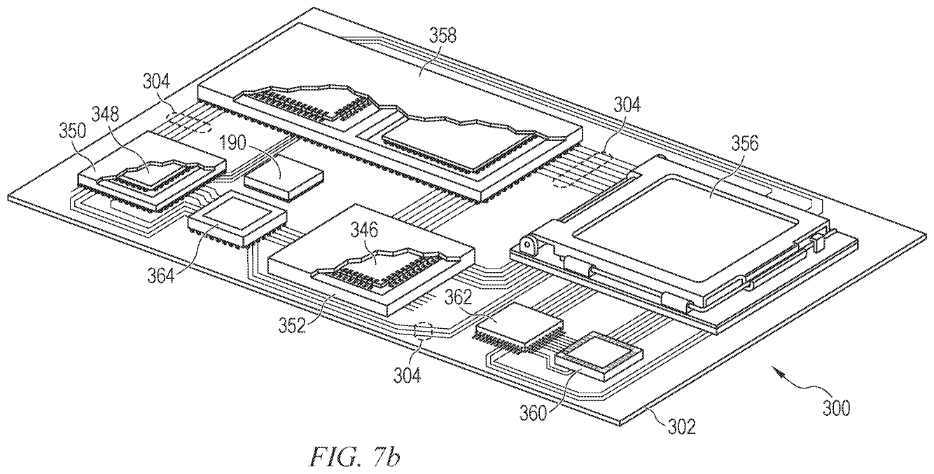

FIGS. 7a and 7b illustrate integrating the above-described semiconductor packages, e.g., SiP module 190, into a larger electronic device 300. FIG. 7a illustrates a partial cross-section of SiP module 190 mounted onto a printed circuit board (PCB) or other substrate 302 as part of electronic device 300. Bumps 194 are reflowed onto conductive layer 304 of PCB 302 to physically attach and electrically connect SiP module 190 to the PCB. In other embodiments, thermocompression or another suitable attachment and connection methods are used. In some embodiments, an adhesive or underfill layer is used between SiP module 190 and PCB 302. Semiconductor die 180 are electrically coupled to conductive layer 304 through bumps 194, interconnect structure 130, conductive pillars 140, and interconnect structure 160.

FIG. 7b illustrates electronic device 300 having a chip carrier substrate or PCB 302 with a plurality of semiconductor packages disposed on a surface of PCB 302, including SiP module 190. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 7b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a first interconnect structure;
disposing a pre-molded bridge die over the first interconnect structure;
depositing an encapsulant over the pre-molded bridge die;
disposing a second interconnect structure over the encapsulant and pre-molded bridge die;
disposing a first semiconductor die over the second interconnect structure within a footprint of the pre-molded bridge die; and
disposing a second semiconductor die over the second interconnect structure within the footprint of the pre-molded bridge die.

2. The method of claim 1, further including forming the pre-molded bridge die by:
providing a bridge die; and
depositing a second encapsulant over the bridge die.

3. The method of claim 2, further including forming a plurality of micropillars over the bridge die prior to depositing the second encapsulant.

4. The method of claim 2, further including forming the pre-molded bridge die by forming a protective layer over the bridge die prior to depositing the second encapsulant.

5. The method of claim 1, further including planarizing the encapsulant and pre-molded bridge die to expose an interconnect structure of the pre-molded bridge die prior to disposing the second interconnect structure.

6. The method of claim 1, further including forming a conductive pillar through the encapsulant from the first interconnect structure to the second interconnect structure.

7. A method of making a semiconductor device, comprising:
providing a first interconnect structure;
disposing a pre-molded bridge die over the first interconnect structure;
depositing an encapsulant over the pre-molded bridge die; and
disposing a second interconnect structure over the encapsulant and pre-molded bridge die.

8. The method of claim 7, further including forming the pre-molded bridge die by:
providing a bridge die; and
depositing a second encapsulant over the bridge die.

9. The method of claim 8, further including forming a plurality of micropillars over the bridge die prior to depositing the second encapsulant.

10. The method of claim 8, further including forming the pre-molded bridge die by forming a protective layer over the bridge die prior to depositing the second encapsulant.

11. The method of claim 7, further including planarizing the encapsulant and pre-molded bridge die to expose an interconnect structure of the pre-molded bridge die prior to disposing the second interconnect structure.

12. The method of claim 7, further including forming a conductive pillar through the encapsulant from the first interconnect structure to the second interconnect structure.

13. The method of claim 7, further including:
disposing a first semiconductor die over the second interconnect structure within a footprint of the pre-molded bridge die;
disposing a second semiconductor die over the second interconnect structure within the footprint of the pre-molded bridge die;
depositing a second encapsulant over the first semiconductor die and second semiconductor die; and
forming a solder bump over the first interconnect structure opposite the pre-molded bridge die.

14. A semiconductor device, comprising:
a first interconnect structure;
a pre-molded bridge die disposed over the first interconnect structure;
an encapsulant deposited over the pre-molded bridge die;
a second interconnect structure disposed over the encapsulant and pre-molded bridge die;
a first semiconductor die disposed over the second interconnect structure within a footprint of the pre-molded bridge die; and
a second semiconductor die disposed over the second interconnect structure within the footprint of the pre-molded bridge die.

15. The semiconductor device of claim 14, wherein the pre-molded bridge die includes:
a bridge die; and
a second encapsulant deposited over the bridge die.

16. The semiconductor device of claim 15, wherein the pre-molded bridge die further includes a plurality of micropillars formed over the bridge die.

17. The semiconductor device of claim 15, wherein the pre-molded bridge die includes a protective layer formed over the bridge die.

18. The semiconductor device of claim 14, wherein a surface of the encapsulant is coplanar to a surface of an interconnect structure of the pre-molded bridge die.

19. The semiconductor device of claim 14, further including a conductive pillar extending through the encapsulant from the first interconnect structure to the second interconnect structure.

20. A semiconductor device, comprising:
a first interconnect structure;
a pre-molded bridge die disposed over the first interconnect structure;
an encapsulant deposited over the pre-molded bridge die; and
a second interconnect structure disposed over the encapsulant and pre-molded bridge die.

21. The semiconductor device of claim 20, wherein the pre-molded bridge die includes:
a bridge die; and
a second encapsulant deposited over the bridge die.

22. The semiconductor device of claim 21, wherein the pre-molded bridge die further includes a plurality of micropillars formed over the bridge die.

23. The semiconductor device of claim 21, wherein the pre-molded bridge die includes a protective layer formed over the bridge die.

24. The semiconductor device of claim 20, wherein a surface of the encapsulant is coplanar to a surface of an interconnect structure of the pre-molded bridge die.

25. The semiconductor device of claim 20, further including a conductive pillar extending through the encapsulant from the first interconnect structure to the second interconnect structure.
